(19) United States
(12) Patent Application Publication
(10) Pub. No.: US 2025/0282541 A1
(43) Pub. Date: Sep. 11, 2025

(54) DEFORMABLE CONTAINER AND GAS STORAGE DEVICE

(71) Applicant: Wiwynn Corporation, New Taipei City (TW)

(72) Inventors: Hsien-Chieh Hsieh, New Taipei City (TW); Fu-Sheng Cheng, New Taipei City (TW)

(73) Assignee: Wiwynn Corporation, New Taipei City (TW)

(21) Appl. No.: 18/776,279

(22) Filed: Jul. 18, 2024

(30) Foreign Application Priority Data
Mar. 8, 2024 (TW) 113108493

(51) Int. Cl. B65D 88/52; B65D 88/00

(52) U.S. Cl. CPC B65D 88/52; B65D 88/005

(57) ABSTRACT

A deformable container includes a bag body, a first connecting member and a second connecting member. The bag body is formed with an opening. The first connecting member has a first tube portion and a first annular flange protruding from an end of the first tube portion. The first tube portion passes through the opening to be exposed from the bag body. The bag body is pressed against a pressing surface of the first annular flange. The second connecting member has a second tube portion. The second tube portion is sleeved on the first tube portion.

### BACKGROUND OF THE INVENTION

### 1. Field of the Invention

The invention relates to a deformable container and a gas storage device and, more particularly, to a deformable container capable of effectively preventing gas from leaking and a gas storage device equipped with the deformable container.

### 2. Description of the Prior Art

An immersion cooling system uses a cooling liquid to dissipate heat from electronic components by a phase change manner. The cooling liquid evaporates into gas after absorbing the heat generated by the electronic component. Thus, the immersion cooling system is usually equipped with a gas storage device for temporarily storing the gas of the cooling liquid and controlling the pressure. A container of the gas storage device is connected to a cooling tank by a tube. However, the joint surface between the container of the gas storage device and the tube is easily broken due to expansion and contraction, thereby resulting in gas leakage.

### SUMMARY OF THE INVENTION

According to an embodiment of the invention, a deformable container comprises a bag body, a first connecting member and a second connecting member. The bag body is formed with an opening. The first connecting member has a first tube portion and a first annular flange protruding from an end of the first tube portion. The first tube portion passes through the opening to be exposed from the bag body. The bag body is pressed against a pressing surface of the first annular flange. The second connecting member has a second tube portion. The second tube portion is sleeved on the first tube portion.

According to another embodiment of the invention, a gas storage device comprises a frame and a deformable container. The deformable container is connected to the frame. The deformable container comprises a bag body, a first connecting member and a second connecting member. The bag body is formed with an opening. The first connecting member has a first tube portion and a first annular flange protruding from an end of the first tube portion. The first tube portion passes through the opening to be exposed from the bag body. The bag body is pressed against a pressing surface of the first annular flange. The second connecting member has a second tube portion. The second tube portion is sleeved on the first tube portion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a gas storage device according to an embodiment of the invention.

FIG. 2 is a perspective view illustrating a deformable container shown in FIG. 1.

FIG. 3 is a partial exploded view illustrating the deformable container shown in FIG. 2.

FIG. 4 is a partial sectional view illustrating the deformable container shown in FIG. 2.

FIG. 5 is a perspective view illustrating a first connecting member shown in FIG. 3 from another viewing angle.

FIG. 6 is a perspective view illustrating a deformable container according to another embodiment of the invention.

FIG. 7 is a partial exploded view illustrating the deformable container shown in FIG. 6.

FIG. 8 is a partial sectional view illustrating the deformable container shown in FIG. 6.

### DETAILED DESCRIPTION

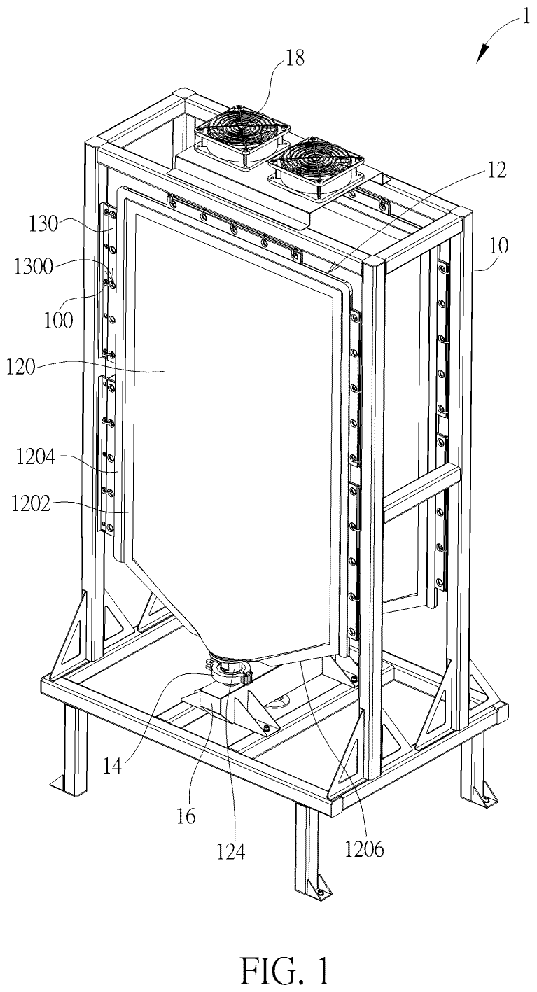

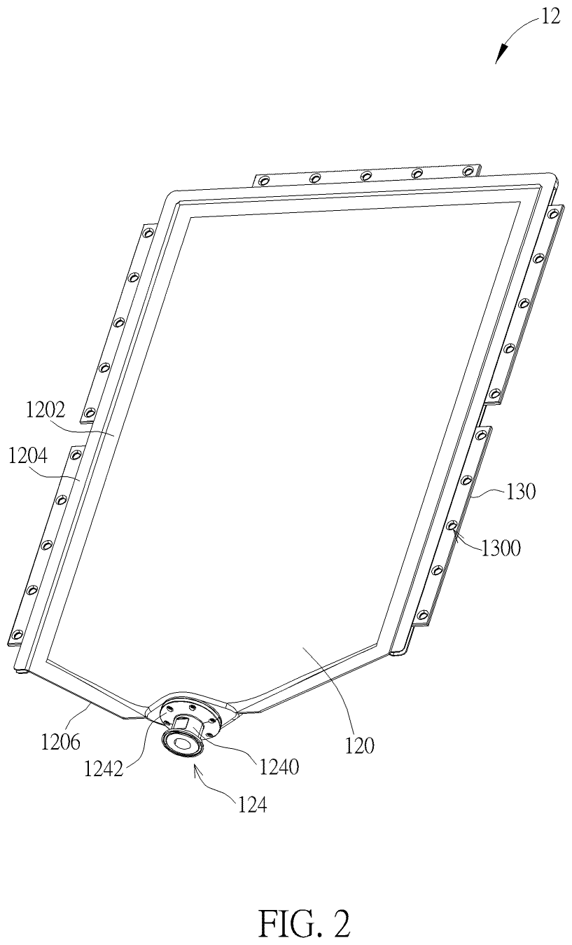

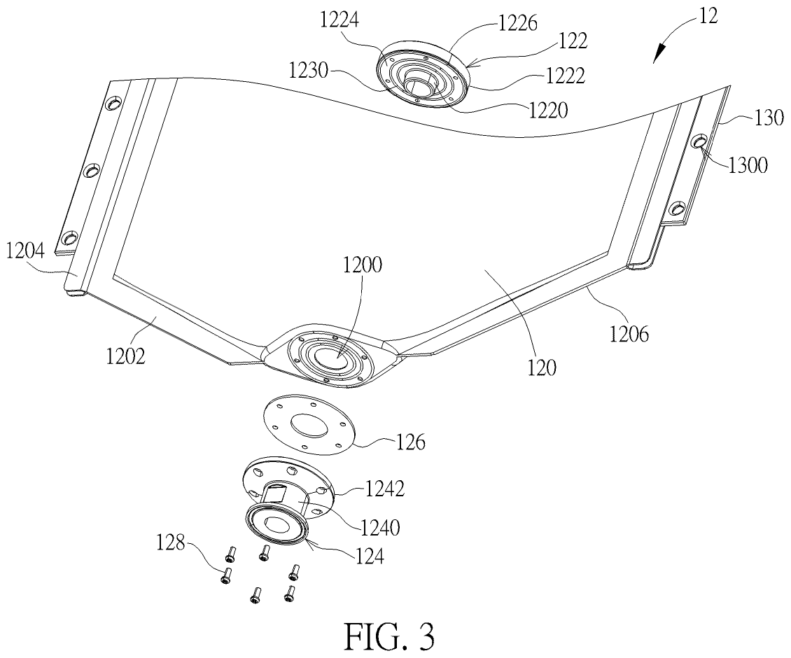

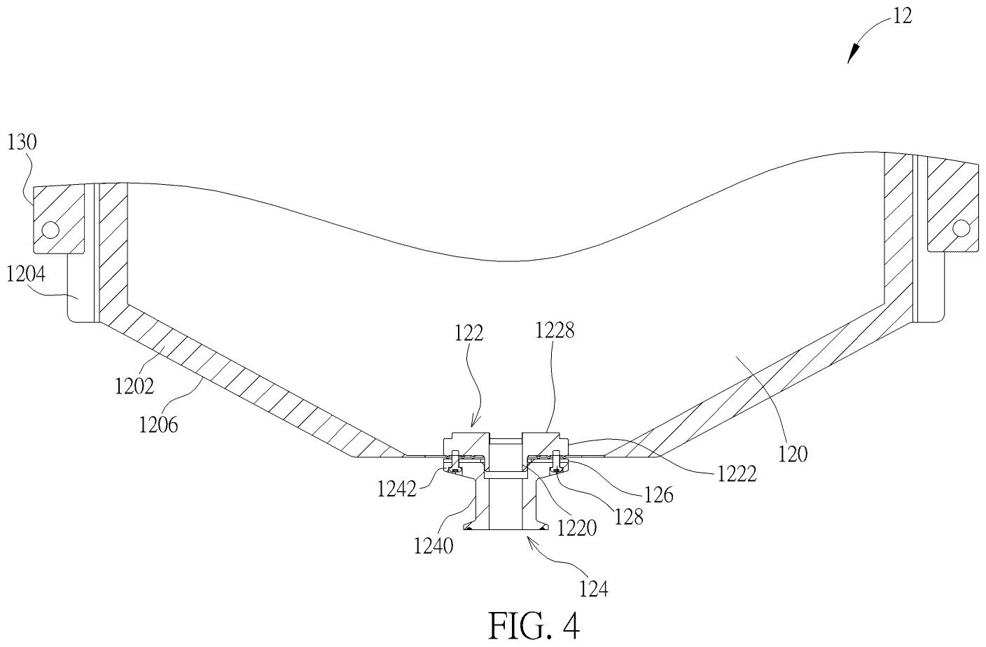

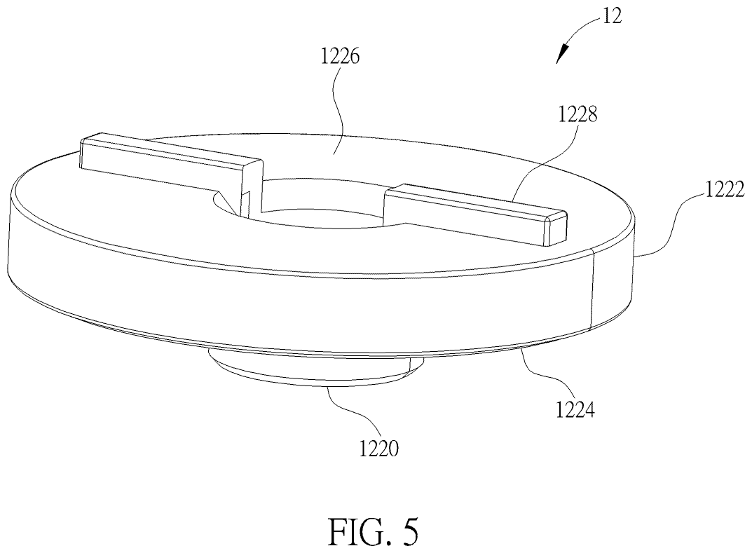

Referring to FIGS. 1 to 5, FIG. 1 is a perspective view illustrating a gas storage device 1 according to an embodiment of the invention, FIG. 2 is a perspective view illustrating a deformable container 12 shown in FIG. 1, FIG. 3 is a partial exploded view illustrating the deformable container 12 shown in FIG. 2, FIG. 4 is a partial sectional view illustrating the deformable container 12 shown in FIG. 2, and FIG. 5 is a perspective view illustrating a first connecting member 122 shown in FIG. 3 from another viewing angle.

As shown in FIG. 1, the gas storage device 1 comprises a frame 10 and a deformable container 12. The deformable container 12 is connected to the frame 10. The gas storage device 1 uses the frame 10 to support the deformable container 12, which may keep the deformable container 12 upright to prevent the deformable container 12 from tipping over and affecting its expansion and contraction performance. It should be noted that the structure of the frame 10 may be designed according to practical applications, so the invention is not limited to the embodiment shown in the figure.

In this embodiment, the deformable container 12 may be connected to an airtight base 16 through a quick release connector 14, and the airtight base 16 may be connected to a cooling tank of an immersion cooling system (not shown) through a tube (not shown). In general, the cooling tank may store a cooling liquid (e.g. dielectric liquid) with a low boiling point. An electronic component (not shown) may be immersed in the cooling liquid. The cooling liquid evaporates and changes into gas after absorbing the heat generated by the electronic component. The deformable container 12 is used to temporarily store the gas of the cooling liquid and control the pressure.

In this embodiment, two deformable containers 12 may be connected to the frame 10 and the airtight base 16 side by side. Furthermore, at least one fan 18 may be disposed on the top of the frame 10, wherein the fan 18 may be disposed between the two deformable containers 12. Accordingly, the downward airflow generated by the fan 18 may dissipate heat from the two deformable containers 12 at the same time. It should be noted that the number of frames 10, deformable containers 12, quick release connectors 14, airtight bases 16 and fans 18 may be adjusted according to practical applications, which make the gas storage device 1 expandable.

As shown in FIGS. 2 to 4, the deformable containers 12 comprises a bag body 120, a first connecting member 122, a second connecting member 124, a sealing member 126, a plurality of fixing members 128 and a plurality of support members 130. The bag body 120 is formed with an opening 1200. In this embodiment, the bag body 120 may be made of plastic film and aluminum foil, the first connecting member 122 and the support members 130 may be made of plastic, the second connecting member 124 may be made of metal or plastic, the sealing member 126 may be an O-ring, and the fixing members 128 may be screws, but the invention is not so limited. In an embodiment, when the bag body 120 is made of plastic film and aluminum foil, the aluminum foil is located between the upper and lower layers of the plastic film, wherein the upper and lower layers of the plastic films are used to be connected with each other and the aluminum foil is used to block light. It should be noted that the aluminum foil may be omitted according to practical applications. In an embodiment, when both the second connecting member 124 and the quick release connector 14 are made of metal, the connecting strength between the second connecting member 124 and the quick release connector 14 may be enhanced.

The first connecting member 122 has a first tube portion 1220 and a first annular flange 1222 protruding from an end of the first tube portion 1220. The first tube portion 1220 of the first connecting member 122 passes through the opening 1200 of the bag body 120 to be exposed from the bag body 120. Furthermore, the bag body 120 is pressed against a pressing surface 1224 of the first annular flange 1222 of the first connecting member 122.

In this embodiment, a non-pressing surface 1226 of the first annular flange 1222 may have a positioning structure 1228, wherein the non-pressing surface 1226 is opposite to the pressing surface 1224. In the invention, the positioning structure 1228 of the first connecting member 122 may be inserted into a positioning hole of a fixture (not shown) first. Then, before the periphery of the bag body 120 is pressed, the opening 1200 of the bag body 120 is sleeved on the first tube portion 1220 of the first connecting member 122. Then, the bag body 120 and the pressing surface 1224 of the first annular flange 1222 are hot pressed and then the periphery of the bag body 120 is hot pressed. Accordingly, the first tube portion 1220 of the first connecting member 122 passes through the opening 1200 of the bag body 120 to be exposed from the bag body 120, and the first annular flange 1222 of the first connecting member 122 is wrapped in the bag body 120. After the bag body 120 and the pressing surface 1224 of the first annular flange 1222 of the first connecting member 122 are hot pressed, the bag body 120 will be tightly connected with the pressing surface 1224 of the first annular flange 1222, thereby enhancing the sealing effect between the bag body 120 and the first connecting member 122 and effectively preventing gas leakage. Furthermore, since the bag body 120 and the pressing surface 1224 of the first annular flange 1222 are pressed together in a surface contact manner, the connecting strength between the bag body 120 and the first annular flange 1222 of the first connecting member 122 will be effectively enhanced, so as to prevent the joint between the bag body 120 and the first annular flange 1222 of the first connecting member 122 from breaking due to expansion and contraction.

In this embodiment, the pressing surface 1224 of the first annular flange 1222 may have a protruding structure 1230, as shown in FIG. 3. The bag body 120 may be pressed against the protruding structure 1230 to increase the contact area between the bag body 120 and the first annular flange 1222, so as to enhance the connecting strength between the bag body 120 and the first annular flange 1222. In this embodiment, the protruding structure 1230 may be composed of a plurality of protruding ribs arranged in concentric circles, but the invention is not so limited.

The second connecting member 124 has a second tube portion 1240 and a second annular flange 1242 protruding from an end of the second tube portion 1240. After the bag body 120 and the first annular flange 1222 of the first connecting member 122 are hot pressed, the sealing member 126 is sleeved on the first tube portion 1220 of the first connecting member 122 and abuts against the bag body 120. Then, the second tube portion 1240 of the second connecting member 124 is sleeved on the first tube portion 1220 of the first connecting member 122, such that the sealing member 126 and the bag body 120 are sandwiched between the first annular flange 1222 of the first connecting member 122 and the second annular flange 1242 of the second connecting member 124. Then, the fixing members 128 pass through the second annular flange 1242, the sealing member 126 and the bag body 120 in sequence to be fixed to the first annular flange 1222, such that the second annular flange 1242 presses the sealing member 126 and the bag body 120 tightly. Then, the second connecting member 124 may be connected to the airtight base 16 through the quick release connector 14, as shown in FIG. 1. The sealing member 126 can prevent gas from leaking from a gap between the first connecting member 122 and the second connecting member 124.

In this embodiment, the first annular flange 1222 may be formed with a plurality of fixing holes (e.g. screw holes), and the second annular flange 1242, the sealing member 126 and the bag body 120 may be formed with a plurality of through holes corresponding to the fixing holes, such that the fixing members 128 may pass through the through holes of the second annular flange 1242, the sealing member 126 and the bag body 120 in sequence to be fixed to the fixing holes of the first annular flange 1222.

The support members 130 are pressed against a periphery of the bag body 120. In this embodiment, the periphery of the bag body 120 may be formed with a first pressing region 1202 and a second pressing region 1204, wherein the second pressing region 1204 surrounds the first pressing region 1202. The support members 130 may be pressed against the second pressing region 1204. In an embodiment, when hot pressing the periphery of the bag body 120, a specific width (e.g. 30 cm) may be reserved around the bag body 120. Then, the first pressing region 1202 is formed by hot pressing the upper and lower layers of the plastic film with a first width (e.g. 10 cm) of the specific width close to the inside of the bag body 120. Then, a part of each support member 130 is placed between the upper and lower layers of the plastic film at a second width (e.g. 20 cm) of the specific width close to the outside of the bag body 120. Then, the upper and lower layers of the plastic film are hot pressed to form the second pressing region 1204, and another part of each support member 130 is exposed from the bag body 120. Since the second pressing region 1204 surrounds the first pressing region 1202, the first pressing region 1202 will not be broken due to the pulling of the support member 130. Accordingly, the sealing effect of the first pressing region 1202 can be ensured.

As shown in FIG. 1, each of the support members 130 may be formed with a plurality of hanging holes 1300, and the frame 10 may comprise a plurality of hanging rings 100. The hanging holes 1300 may be hung on the hanging rings 100, such that the deformable container 12 is connected to the frame 10 by the support members 130. Accordingly, the deformable container 12 may be hung on the frame 10 and keep upright to prevent the deformable container 12 from tipping over and affecting its expansion and contraction performance. It should be noted that the deformable container 12 may be connected to the frame 10 by other fixing or engaging structures, so the invention is not limited to the hanging manner.

In this embodiment, a bottom 1206 of the bag body 120 may be inclined with respect to the first tube portion 1220 of the first connecting member 122 to help recover the liquid condensed from the gas of the cooling liquid.

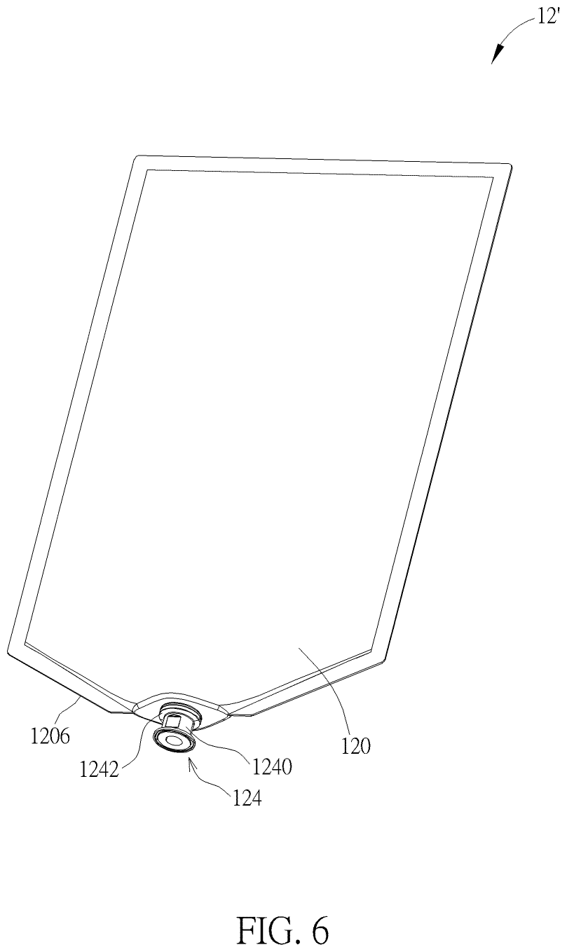

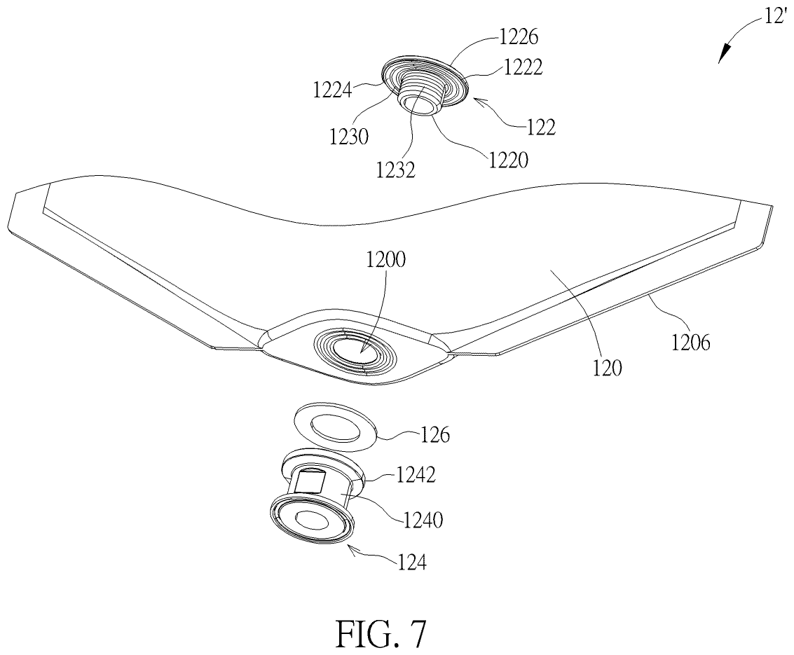

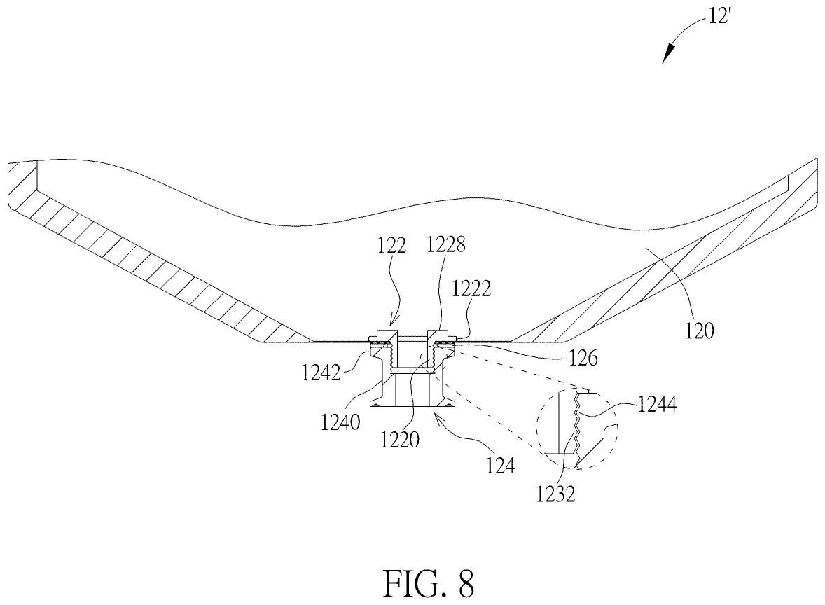

Referring to FIGS. 6 to 8, FIG. 6 is a perspective view illustrating a deformable container 12′ according to another embodiment of the invention, FIG. 7 is a partial exploded view illustrating the deformable container 12′ shown in FIG. 6, and FIG. 8 is a partial sectional view illustrating the deformable container 12′ shown in FIG. 6.

In another embodiment, the aforesaid deformable container 12 may be replaced by the deformable container 12′ shown in FIGS. 6 to 8. The main difference between the deformable container 12′ and the aforesaid deformable container 12 is that the first tube portion 1220 of the first connecting member 122 of the deformable container 12′ has an outer thread 1232, and the second tube portion 1240 of the second connecting member 124 of the deformable container 12′ has an inner thread 1244. The inner thread 1244 and the outer thread 1232 may be screwed with each other, such that the second connecting member 124 is fixed on the first connecting member 122 and the second annular flange 1242 presses the sealing member 126 and the bag body 120 tightly. Therefore, in this embodiment, the fixing members 128, the through holes and the fixing holes mentioned above may be omitted. It should be noted that the deformable container 12′ may also be equipped with the aforesaid support members 130 to be connected with the frame 10 shown in FIG. 1.

As mentioned above, since the bag body and the pressing surface of the first annular flange of the first connecting member are pressed together in a surface contact manner, the connecting strength between the bag body and the first annular flange of the first connecting member will be effectively enhanced, so as to prevent the joint between the bag body and the first annular flange of the first connecting member from breaking due to expansion and contraction. After the bag body and the pressing surface of the first annular flange of the first connecting member are pressed, the bag body will be tightly connected with the pressing surface of the first annular flange, thereby enhancing the sealing effect between the bag body and the first connecting member and effectively preventing gas leakage. Furthermore, the sealing member may be disposed between the first connecting member and the second connecting member to prevent gas from leaking from the gap between the first connecting member and the second connecting member. Moreover, the deformable container may be connected to the frame to keep upright, so as to prevent the deformable container 12 from tipping over and affecting its expansion and contraction performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A deformable container comprising:
a bag body formed with an opening;
a first connecting member having a first tube portion and a first annular flange protruding from an end of the first tube portion, the first tube portion passing through the opening to be exposed from the bag body, the bag body being pressed against a pressing surface of the first annular flange; and
a second connecting member having a second tube portion, the second tube portion being sleeved on the first tube portion.

2. The deformable container of claim 1, further comprising a sealing member sleeved on the first tube portion and abutting against the bag body, wherein the second connecting member further has a second annular flange protruding from an end of the second tube portion, and the sealing member and the bag body are sandwiched between the first annular flange and the second annular flange.

3. The deformable container of claim 2, further comprising a plurality of fixing members, wherein the plurality of fixing members pass through the second annular flange, the sealing member and the bag body in sequence to be fixed to the first annular flange.

4. The deformable container of claim 1, wherein the first tube portion has an outer thread, the second tube portion has an inner thread, and the inner thread and the outer thread are screwed with each other.

5. The deformable container of claim 1, wherein the pressing surface has a protruding structure and the bag body is pressed against the protruding structure.

6. The deformable container of claim 1, wherein a bottom of the bag body is inclined with respect to the first tube portion.

7. The deformable container of claim 1, further comprising a plurality of support members pressed against a periphery of the bag body.

8. The deformable container of claim 7, wherein the periphery of the bag body is formed with a first pressing region and a second pressing region, the second pressing region surrounds the first pressing region, and the plurality of support members are pressed against the second pressing region.

9. The deformable container of claim 7, wherein each of the plurality of support members is formed with a plurality of hanging holes.

10. The deformable container of claim 1, wherein a non-pressing surface of the first annular flange has a positioning structure and the non-pressing surface is opposite to the pressing surface.

11. A gas storage device comprising:
a frame; and
a deformable container connected to the frame, the deformable container comprising:
a bag body formed with an opening;
a first connecting member having a first tube portion and a first annular flange protruding from an end of the first tube portion, the first tube portion passing through the opening to be exposed from the bag body, the bag body being pressed against a pressing surface of the first annular flange; and
a second connecting member having a second tube portion, the second tube portion being sleeved on the first tube portion.

12. The gas storage device of claim 11, wherein the deformable container further comprises a sealing member sleeved on the first tube portion and abutting against the bag body, the second connecting member further has a second annular flange protruding from an end of the second tube portion, and the sealing member and the bag body are sandwiched between the first annular flange and the second annular flange.

13. The gas storage device of claim 12, wherein the deformable container further comprises a plurality of fixing members, and the plurality of fixing members pass through the second annular flange, the sealing member and the bag body in sequence to be fixed to the first annular flange.

14. The gas storage device of claim 11, wherein the first tube portion has an outer thread, the second tube portion has an inner thread, and the inner thread and the outer thread are screwed with each other.

15. The gas storage device of claim 11, wherein the pressing surface has a protruding structure and the bag body is pressed against the protruding structure.

16. The gas storage device of claim 11, wherein a bottom of the bag body is inclined with respect to the first tube portion.

17. The gas storage device of claim 11, wherein the deformable container further comprises a plurality of support members pressed against a periphery of the bag body, and the deformable container is connected to the frame by the plurality of support members.

18. The gas storage device of claim 17, wherein the periphery of the bag body is formed with a first pressing region and a second pressing region, the second pressing region surrounds the first pressing region, and the plurality of support members are pressed against the second pressing region.

19. The gas storage device of claim 17, wherein each of the plurality of support members is formed with a plurality of hanging holes, the frame comprises a plurality of hanging rings, and the plurality of hanging holes are hung on the plurality of hanging rings.

20. The gas storage device of claim 11, wherein a non-pressing surface of the first annular flange has a positioning structure and the non-pressing surface is opposite to the pressing surface.
